(19) United States
(12) Patent Application Publication
(10) Pub. No.: US 2026/0304739 A1
(43) Pub. Date: Oct. 1, 2026

(54) SEMICONDUCTOR DEVICE COMPRISING AN ACTIVE PATTERN HAVING A CURVED SHAPE

(71) Applicant: SAMSUNG ELECTRONICS CO., LTD., Suwon-si (KR)

(72) Inventors: Jaehee LEE, Suwon-si (KR); Dongjoo MIN, Suwon-si (KR); Pyung MOON, Suwon-si (KR); Mina SEOL, Suwon-si (KR); Kongsoo LEE, Suwon-si (KR); Soonwook JUNG, Suwon-si (KR)

(73) Assignee: SAMSUNG ELECTRONICS CO., LTD., Suwon-si (KR)

(21) Appl. No.: 19/577,792

(22) Filed: Mar. 25, 2026

(30) Foreign Application Priority Data
Mar. 27, 2025 (KR) 10-2025-0039799

(51) Int. Cl. H10B 12/00; H10D 62/17; H10D 64/27

(52) U.S. Cl. CPC H10B 12/30; H10B 12/05; H10D 62/235; H10D 64/517

(57) ABSTRACT

A semiconductor device includes an active pattern extending in a first horizontal direction and having at least one concave portion, the active pattern including a first source/drain region, a second source/drain region, and a channel region between the first and second source/drain regions, in which the at least one concave portion is defined along a side surface of the channel region and the first and second source/drain regions centered on the channel region, a bit line extending in a vertical direction and contacting the first source/drain region of the active pattern, and a gate electrode overlapping at least a portion of the channel region of the active pattern in the vertical direction and extending in a second horizontal direction, intersecting the first horizontal direction.

### CROSS-REFERENCE TO RELATED APPLICATIONS

This application claims benefit of priority to Korean Patent Application No. 10-2025-0039799 filed on Mar. 27, 2025 in the Korean Intellectual Property Office, the disclosure of which is incorporated herein by reference in its entirety.

### BACKGROUND

The present inventive concept relates to a semiconductor device and a method of manufacturing the same.

Research has been conducted to reduce the size of elements constituting semiconductor devices and to improve performance thereof. For example, research has been conducted to reliably and stably form elements with a reduced size in a DRAM, but as the size of the elements is reduced, the performance of semiconductor devices may deteriorate.

### SUMMARY

An aspect of the present inventive concept is to provide a semiconductor device having improved reliability and improved performance.

According to an aspect of the present inventive concept, a semiconductor device includes: transistors stacked in a vertical direction; a bit line electrically connected to a first side of each of the transistors; and a data storage structure electrically connected to a second side of each of the transistors. Each of the transistors includes: an active pattern including a first source/drain region, a channel region, and a second source/drain region arranged sequentially in a first horizontal direction, the first horizontal direction being perpendicular to the vertical direction and a direction from the bit line toward the data storage structure; a gate electrode vertically overlapping the channel region; and a gate dielectric layer disposed between the gate electrode and the channel region, in which at least a portion of a side surface of each of the first source/drain region, the channel region, and the second source/drain region is curved, a thickness of the channel region in the vertical direction is smaller than a thickness of the first source/drain region in the vertical direction, and a thickness of the first source/drain region in the vertical direction is smaller than a thickness of the second source/drain in the vertical direction.

According to an aspect of the present inventive concept, a semiconductor device includes: a memory structure; and a peripheral structure overlapping the memory structure in a vertical direction and including a peripheral circuit, in which the memory structure includes: transistors sequentially stacked in the vertical direction, each of the transistors including an active pattern including a first source/drain region, a channel region, and a second source/drain region sequentially arranged in a first horizontal direction, perpendicular to the vertical direction, and having at least one concave portion, a gate electrode vertically overlapping the channel region and having at least one convex portion corresponding to the at least one concave portion and being convex toward the active pattern, and a gate dielectric layer disposed between the gate electrode and the channel region; a bit line electrically connected to the first source/drain regions of the transistors; and a data storage structure electrically connected to the second source/drain regions of the transistors.

According to an aspect of the present inventive concept, a semiconductor device includes: an active pattern extending in a first horizontal direction and having at least one concave portion, the active pattern including a first source/drain region; a second source/drain region; and a channel region disposed between the first and second source/drain regions, in which the at least one concave portion is defined along a side surface of the channel region and the first and second source/drain regions centered on the channel region; a bit line extending in a vertical direction and contacting the first source/drain region of the active pattern; and a gate electrode overlapping at least a portion of the channel region of the active pattern in the vertical direction and extending in a second horizontal direction, intersecting the first horizontal direction.

### BRIEF DESCRIPTION OF DRAWINGS

The and other aspects, features, and advantages of the present inventive concept will be more clearly understood from the following detailed description, taken in conjunction with the accompanying drawings, in which:

FIG. 1 is a conceptual perspective view illustrating a semiconductor device according to embodiments;

FIG. 2 is a diagram illustrating an example of a semiconductor device according to an embodiment;

FIG. 3A is a cross-sectional view of a region taken along line I-I’ of FIG. 2;

FIG. 3B is a partially enlarged view illustrating a region marked ‘A’ of FIG. 3A;

FIG. 4 is a vertical cross-sectional view illustrating an example of a semiconductor device according to an embodiment;

FIG. 5 is a vertical cross-sectional view illustrating an example of a semiconductor device according to an embodiment;

FIGS. 6A, 6B, 6C, 6D, 6E, 6F, 6G, 6H, 6I and 6J are vertical cross-sectional views illustrating a method of forming a semiconductor device according to an embodiment of the present inventive concept; and

FIGS. 7A, 7B and 7C are vertical cross-sectional views illustrating a method of forming a semiconductor device according to an embodiment of the present inventive concept.

### DETAILED DESCRIPTION

Hereinafter, terms, such as ‘above,’ ‘upper portion,’ ‘upper surface,’ ‘below,’ ‘lower portion,’ ‘lower surface,’ ‘side surface,’ ‘top,’ ‘bottom,’ etc. are understood to refer to the drawings, except in cases in which they are indicated separately by reference symbols. Terms, such as "upper,” "middle,” and "lower,” etc. may be replaced with other terms, such as “first,” “second,” and “third,” and used to describe components of the specification. Terms, such as “first,” “second,” and “third,” etc. may be used to describe various components, but the components are not limited by the terms, and “first component” may be named “second component.”

Hereinafter, embodiments of the present inventive concept are described with reference to the accompanying drawings.

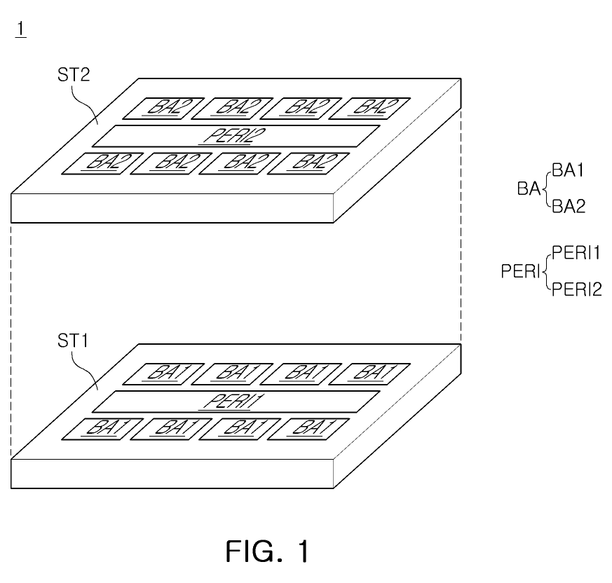

FIG. 1 is a conceptual perspective view illustrating a semiconductor device according to embodiments.

Referring to FIG. 1, a semiconductor device 1 according to an embodiment may include a memory structure ST1 and a peripheral structure ST2 vertically overlapping the memory structure ST1. The memory structure ST1 may include a memory region, and the peripheral structure ST2 may include a peripheral circuit.

The semiconductor device 1 may include a plurality of banks BA and a peripheral region PERI.

The peripheral region PERI may include a first peripheral region PERI1 within the memory structure ST1 and a second peripheral region PERI2 within the peripheral structure ST2. The peripheral region PERI may be a peripheral region in which peripheral circuits for input/output of data or commands or input of power/ground, are arranged.

Each of the plurality of banks BA may include a first bank region BA1 within the memory structure ST1 and a second bank region BA2 within the peripheral structure ST2.

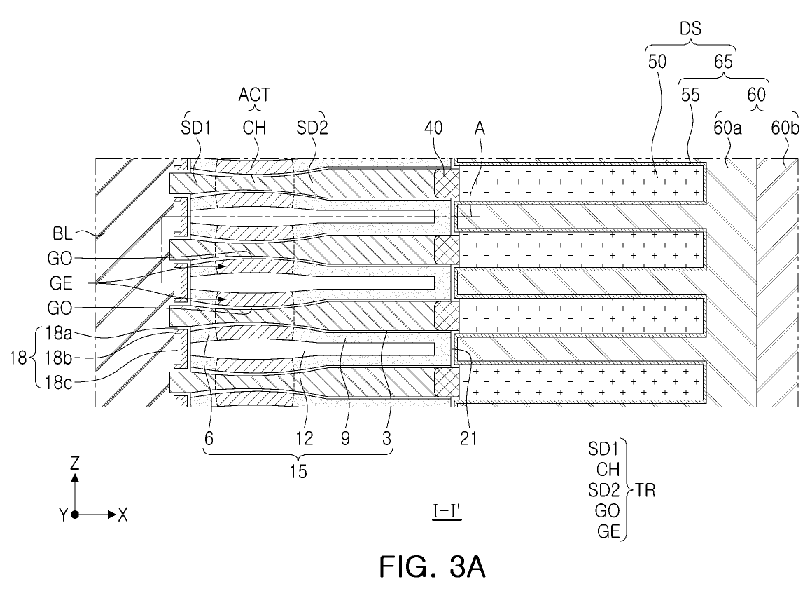

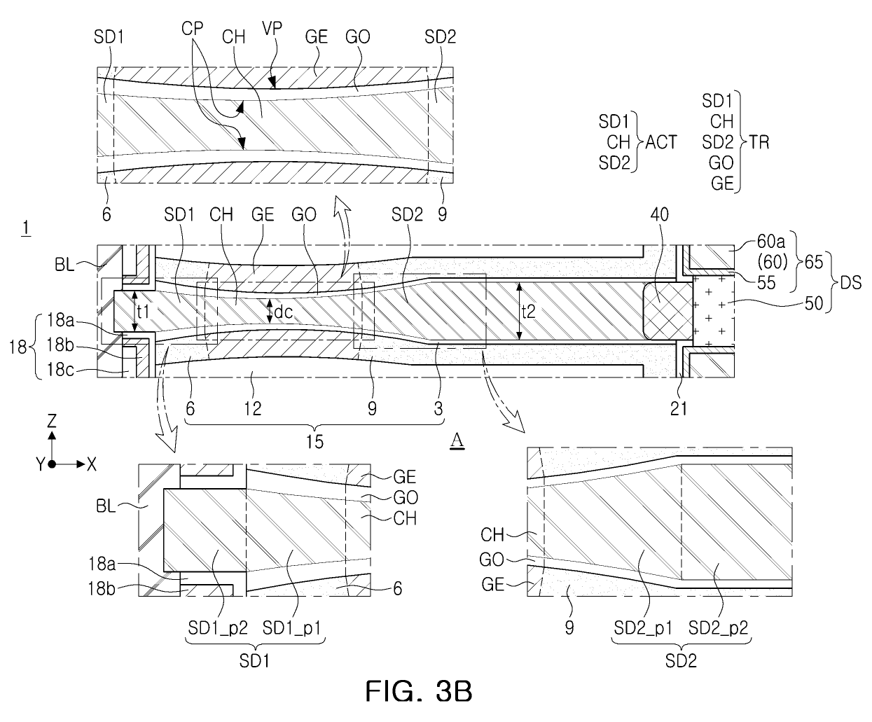

The first bank region BA1 within the memory structure ST1 may include memory cells (TR, DS of FIG. 3A). Each of the memory cells (TR and DS of FIG. 3A) may include a data storage structure (DS of FIG. 3A) that may serve as information storage and a transistor (TR of FIG. 3A) electrically connected to the data storage structure DS.

The second bank region BA2 within the peripheral structure ST2 may include peripheral circuits, such as a sense amplifier and a sub-word line driver.

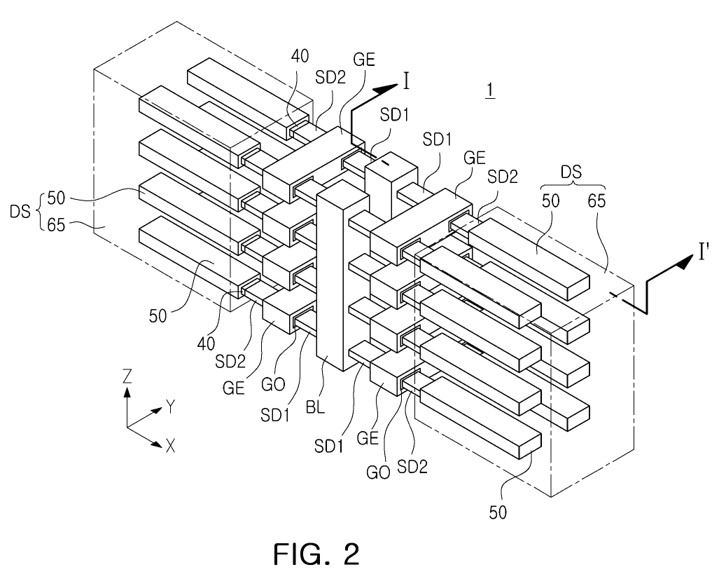

FIG. 2 is a diagram illustrating an example of a semiconductor device according to an embodiment.

FIG. 3A is a cross-sectional view illustrating a region taken along line I-I’ of FIG. 2.

FIG. 3B is a partially enlarged view illustrating a region indicated by ‘A’ in FIG. 3A.

Hereinafter, examples of regions in which the memory cells (TR and DS of FIG. 3A) are arranged in the first bank region BA1 of the memory structure ST1 of the semiconductor device 1 described above with reference to FIG. 1 will be described with reference to FIGS. 2, 3A, and 3B.

Referring to FIGS. 2, 3A, and 3B, the semiconductor device 1 may include bit lines BL and the data storage structures DS.

Each of the bit lines BL may extend in a vertical direction Z. The bit lines BL may be disposed between the data storage structures DS. The memory structure (ST1 of FIG. 1) and the peripheral structure (ST2 of FIG. 1) described above with reference to FIG. 1 may overlap in the vertical direction Z.

In embodiments, a direction, perpendicular to the vertical direction Z and from the bit lines BL toward the data storage structures DS, may be defined as a first horizontal direction X. For example, the first horizontal direction X may be defined as a direction from one of the bit lines BL toward one of the data storage structures DS.

The bit lines BL may be arranged to be spaced apart from each other in a second horizontal direction Y, perpendicular to the vertical direction Z and the first horizontal direction X.

Hereinafter, the descriptions are given based on one of the bit lines BL and one of the data storage structures DS.

The semiconductor device 1 may further include transistors TR. The transistors TR may be stacked and spaced apart from each other in the vertical direction Z. The transistors TR may be disposed between the bit line BL and the data storage structure DS. The bit line BL may be electrically connected to a first side of each of the transistors TR, and the data storage structure DS may be electrically connected to a second side of each of the transistors TR. The transistors TR and the data storage structure DS may form the memory cells TR and DS.

Each of the transistors TR may include a first source/drain region SD1, a channel region CH, a second source/drain region SD2, a gate dielectric layer GO, and a gate electrode GE.

In each of the transistors TR, the first source/drain region SD1, the channel region CH, and the second source/drain region SD2 may be arranged sequentially in the first horizontal direction X.

The first source/drain regions SD1 of the transistors TR may be electrically connected to the bit line BL. The second source/drain regions SD2 of the transistors TR may be electrically connected to the data storage structure DS.

In each of the transistors TR, the gate electrode GE may vertically overlap the channel region CH, and the gate dielectric layer GO may be disposed between the gate electrode GE and the channel region CH. In each of the transistors TR, the gate electrode GE may extend in the second horizontal direction Y and surround the channel region CH. For example, in the second horizontal direction Y, the gate electrode GE may cover a lower surface, an upper surface, and side surfaces of the channel region CH. The gate electrodes GE of the transistors TR may be word lines.

The semiconductor device 1 may include active patterns ACT stacked in the vertical direction Z and spaced apart from each other. Each of the active patterns ACT may include the first source/drain region SD1, the channel region CH, and the second source/drain region SD2 sequentially arranged in the first horizontal direction X. For example, the first source/drain regions SD1, the channel regions CH, and the second source/drain regions SD2 may be arranged within the active patterns ACT.

At least a portion of a side surface of each of the first source/drain region SD1, the channel region CH, and the second source/drain region SD2 may be curved. For example, the active pattern ACT may have at least one concave portion CP concave toward the center of the active pattern ACT. That is, the at least one concave portion CP may be formed across the first source/drain region SD1, the channel region CH, and the second source/drain region SD2. Here, the center of the active pattern ACT may be defined in a direction, parallel to the first horizontal direction X.

The first source/drain region SD1 may include a first portion SD1_p1 adjacent to the channel region CH and a second portion SD1_p2 connected to the first portion SD1_p1 and electrically connected to the bit line BL. In an embodiment, the first portion SD1_p1 may be referred to as a 1-1 portion, and the second portion SD1_p2 may be referred to as a 1-2 portion.

At least a portion of the side surface of the first portion SD1_p1 may be curved. For example, a thickness of the first portion SD1_p1 in the vertical direction Z may decrease in the first horizontal direction X.

The second source/drain region SD2 may include a first portion SD2_p1 adjacent to the channel region CH and a second portion SD2_p2 connected to the first portion SD2_p1 and electrically connected to the data storage structure DS. In an embodiment, the first portion SD2_p1 may be referred to as a 2-1 portion, and the second portion SD2_p2 may be referred to as a 2-2 portion.

At least a portion of the side surface of the first portion SD2_p1 may be curved. For example, a thickness of the first portion SD2_p1 in the vertical direction Z may increase in the first horizontal direction X.

The thicknesses of the first source/drain region SD1, the channel region CH, and the second source/drain region SD2 in the vertical direction Z may be different from each other. In another perspective, the thickness of the active pattern ACT in the vertical direction Z may vary depending on the first horizontal direction X.

A thickness t1 of the first source/drain region SD1 in the vertical direction Z may be greater than a thickness dc of the channel region CH in the vertical direction Z. Here, the thickness t1 may refer to the maximum thickness of the first source/drain region SD1. For example, the thickness t1 may refer to a thickness of the second portion SD1_p2. Meanwhile, a thickness dc may refer to the minimum thickness of the channel region CH defined by the concave portion CP. The thickness dc may refer to a thickness defined at the center of the channel region CH.

A thickness t2 of the second source/drain region SD2 in the vertical direction Z may be greater than the thickness t1 of the first source/drain region SD1 in the vertical direction Z. Here, the thickness t2 may refer to the maximum thickness of the second source/drain region SD2. For example, the thickness t2 may refer to a thickness of the second portion SD2_p2.

A thickness of a region may mean a dimension of the region in a direction perpendicular to a planar surface of the region. The thickness may be any one of an average thickness, a maximum thickness, a minimum thickness, or a thickness measured in a predetermined region, unless contradictory to another definition explicitly described. In one example, the thickness of a specific region of an element may be determined by defining a predetermined number (e.g., 5) of points to the left and the predetermined number (e.g., 5) of points to the right from a reference center point of the specific region at equal intervals (or non-equal intervals, alternatively), measuring a thickness of each of the points at equal intervals (or non-equal intervals, alternatively), and obtaining an average value therefrom. Alternatively, the thickness may be the maximum thickness or the minimum thickness of the multiple measurements. Alternatively, the thickness may be a thickness of the reference center point in the measured region. In one example, an optical microscope or a scanning electron microscope (SEM) may be used in the measurement, although the present disclosure is not limited thereto. Other measurement methods and/or tools appreciated by one of ordinary skill in the art, even if not described in the present disclosure, may also be used.

A length of the second source/drain region SD2 in the first horizontal direction X may be greater than a length of the first source/drain region SD1 in the first horizontal direction X.

At least a portion of the side surface of the gate electrode GE may be curved. For example, the gate electrode GE may have a convex portion VP in a direction toward the channel region CH.

Each of the gate dielectric layers GO may be disposed between the channel region CH in a corresponding active pattern ACT among the active patterns ACT and the gate electrode GE. The thickness of the gate dielectric layer GO may not be uniform. For example, the thickness of the gate dielectric layer GO may decrease in the first horizontal direction X.

The active patterns ACT may be disposed between the bit line BL and the data storage structure DS. The active patterns ACT may have a shape extending into the bit line BL. The first source/drain regions SD1 of the active patterns ACT may extend into the bit line BL. The active patterns ACT may be formed of a semiconductor material. For example, the active patterns ACT may be formed of a semiconductor material, such as single crystal silicon.

The data storage structure DS may include conductive pillars 50 extending in the first horizontal direction X and a pattern structure 65 covering the conductive pillars 50.

The pattern structure 65 may include an electrode pattern 60 covering the conductive pillars 50 and a dielectric layer 55 between the conductive pillars 50 and the electrode pattern 60. The electrode pattern 60 may cover an upper surface, a lower surface, and side surfaces of each of the conductive pillars 50 and may cover the side surfaces of each of the conductive pillars 50 facing each other in the second horizontal direction Y.

The electrode pattern 60 may include a first conductive layer 60a in contact with the dielectric layer 55 and a second conductive layer 60b spaced apart from the dielectric layer 55 and in contact with the first conductive layer 60a.

The data storage structure DS may be memory cell capacitors capable of storing information in a memory, such as DRAM. For example, in the data storage structure DS, each of the conductive pillars 50 may be a first electrode of a memory cell capacitor, the first conductive layer 60a of the electrode pattern 60 may be a second electrode of the memory cell capacitor, and the dielectric layer 55 may be a capacitor dielectric layer of the memory cell capacitor. The second conductive layer 60b of the electrode pattern 60 may be a plate electrode pattern.

The semiconductor device 1 may further include conductive patterns 40. The conductive pillars 50 may include a conductive material, such as Mo, W, etc.

Each of the conductive patterns 40 may include a metal-semiconductor compound region in contact with the second source/drain region SD2 of a corresponding transistor among the transistors TR. The metal-semiconductor compound region may include a metal silicide. For example, the metal-semiconductor compound region may include at least one of TiSi, MoSi, ZrSi, or CoSi.

The semiconductor device 1 may further include a first insulating structure 15, a second insulating structure 18, and a buffer insulating layer 21.

Between the active patterns ACT adjacent to each other in the vertical direction Z, the first insulating structure 15 may include a first insulating layer 12 disposed between the active patterns ACT, second insulating layers 6 disposed between the gate electrodes GE and the bit line BL, a third insulating layer 9 disposed between the gate electrodes GE and the data storage structure DS and between the first insulating layer 12 and the data storage structure DS, and a fourth insulating layer 3 disposed between the gate dielectric layers GO and the data storage structure DS. The fourth insulating layer 3 and the gate dielectric layer GO may be a single component, and a boundary between the fourth insulating layer 3 and the gate dielectric layer GO may not be apparent.

Each of the gate dielectric layers GO is disposed between the channel region CH within a corresponding active pattern ACT among the active patterns ACT and the gate electrode GE and may extend between the second insulating layer 6 and the first source/drain region SD1 within the active pattern ACT. Between the active patterns ACT adjacent to each other in the vertical direction Z, the second insulating structure 18 may include a fifth insulating layer 18c in contact with the bit line BL and disposed between the first insulating structure 15 and the bit line BL, a sixth insulating layer 18b disposed between the fifth insulating layer 18c and the first insulating structure 15 and coverings upper and lower surfaces of the fifth insulating layer 18c, and a seventh insulating layer 18a disposed between the sixth insulating layer 18b and the first insulating structure 15 and covering upper and lower surfaces of the sixth insulating layer 18b.

The buffer insulating layer 21 may be disposed between the conductive patterns 40 adjacent to each other in the vertical direction Z and may be disposed between the first insulating structure 15 and the data storage structure DS. The buffer insulation layer 21 may prevent leakage current between the electrode pattern 60 and the conductive patterns 40.

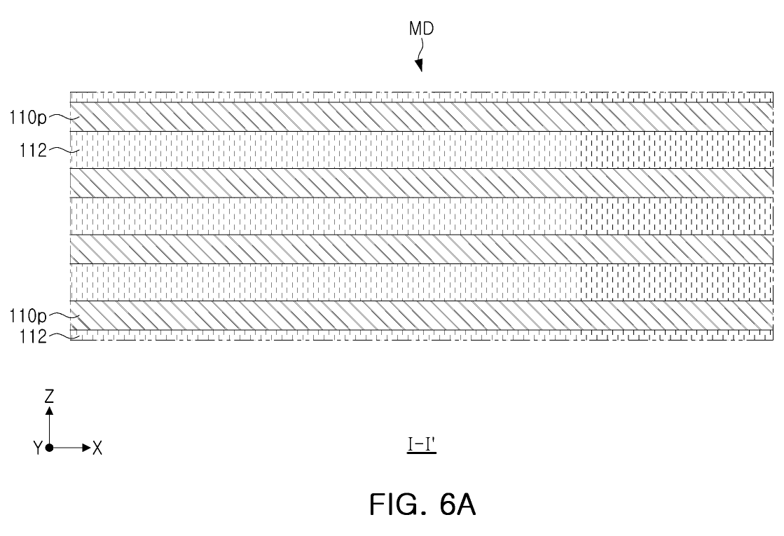

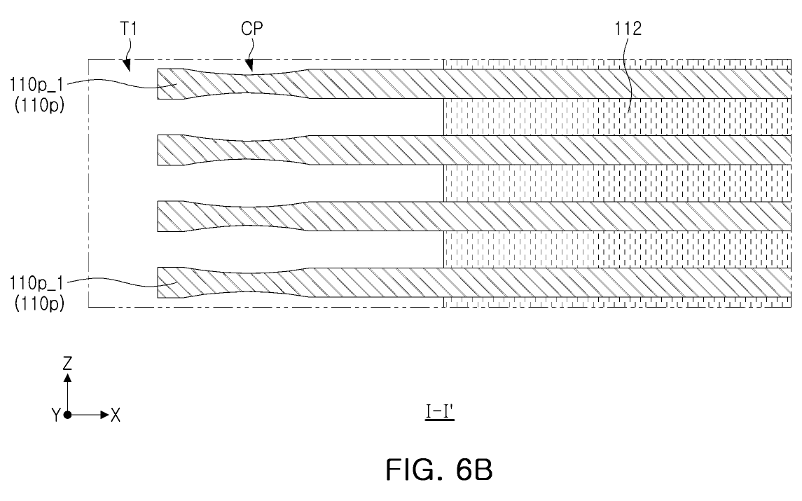

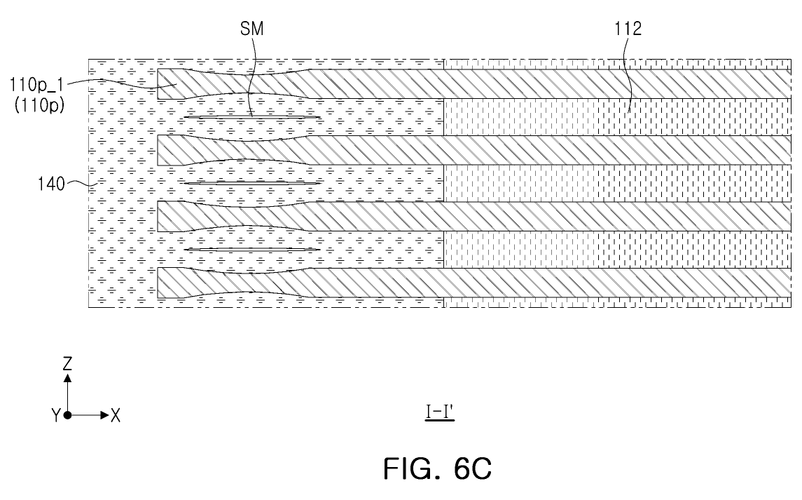

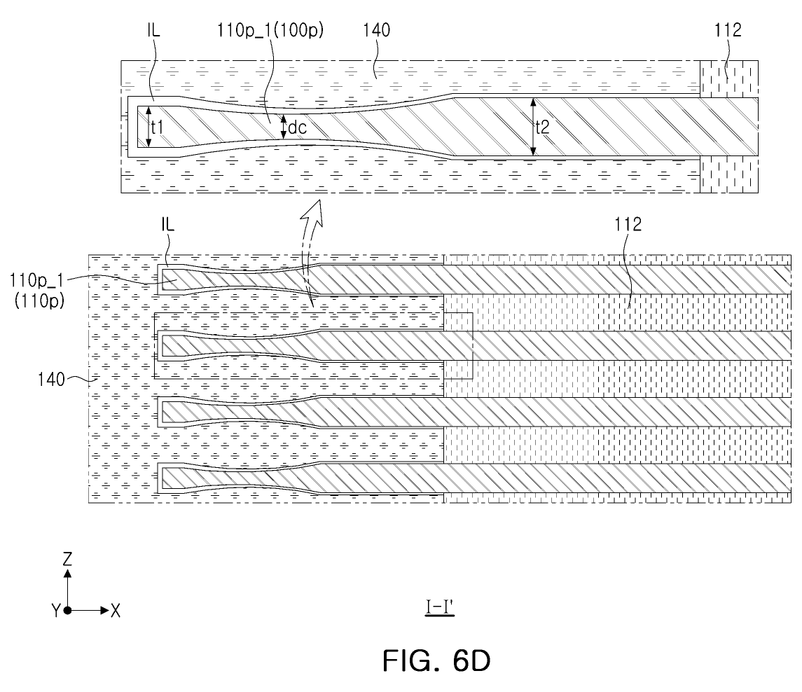

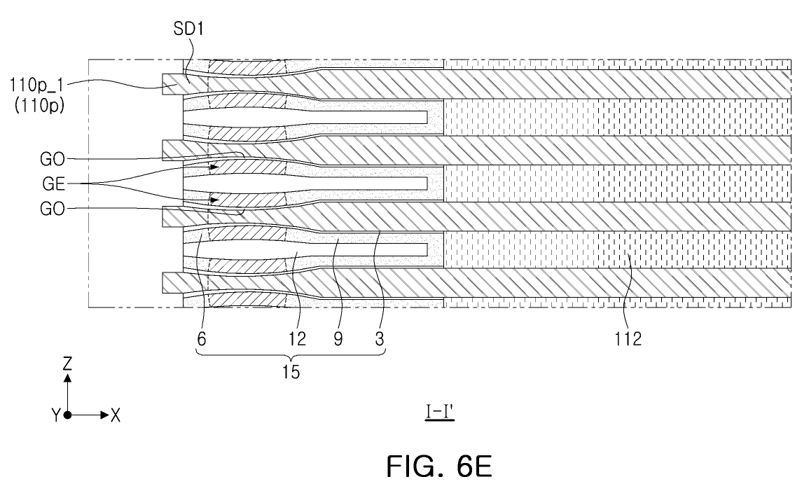

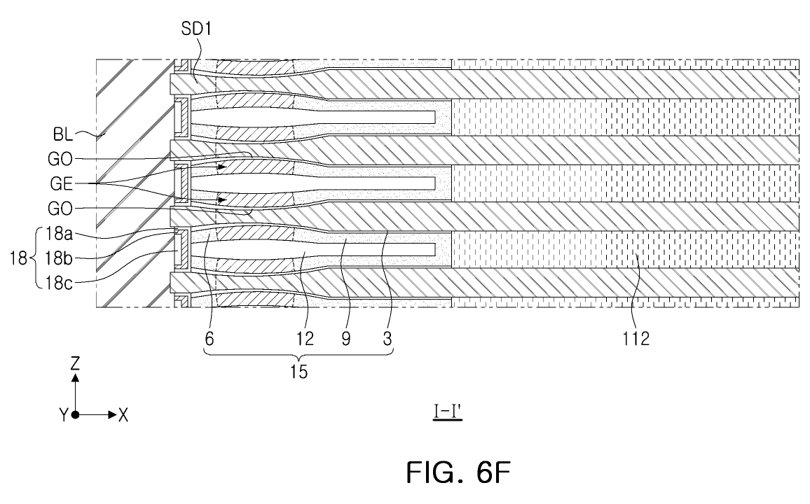

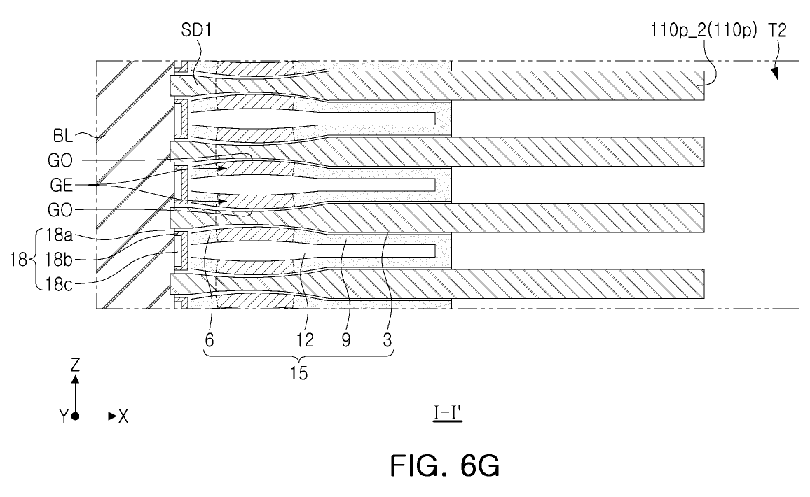

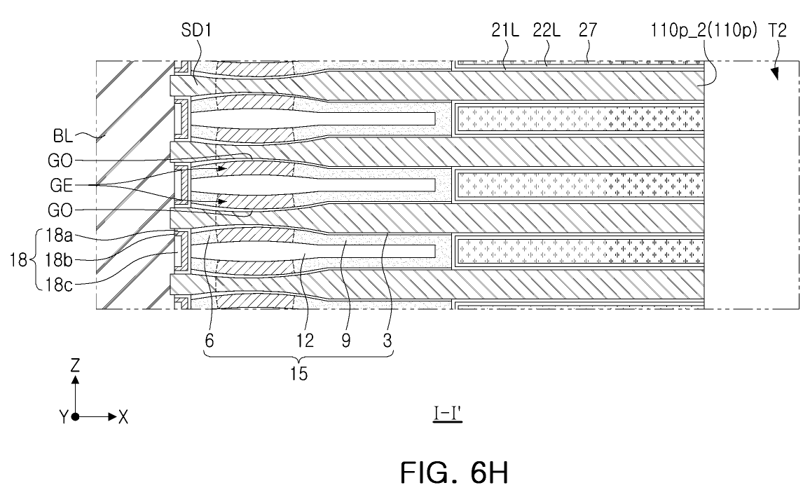

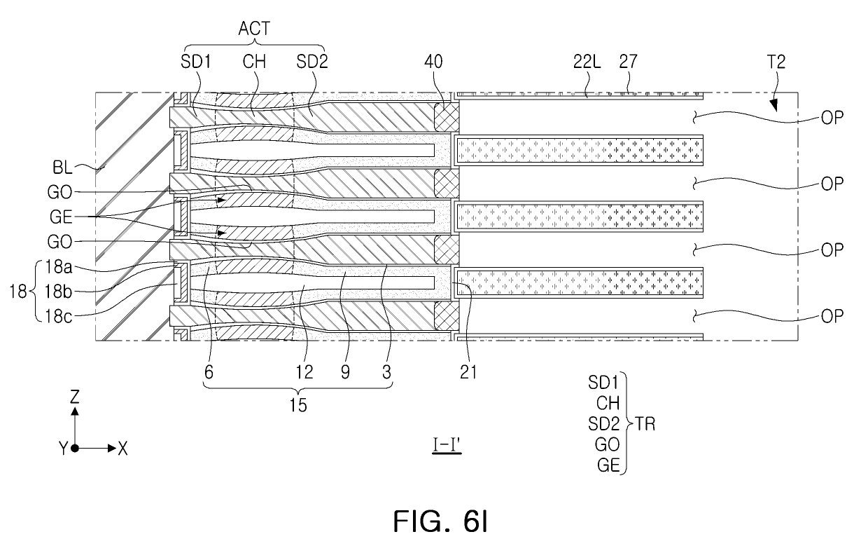

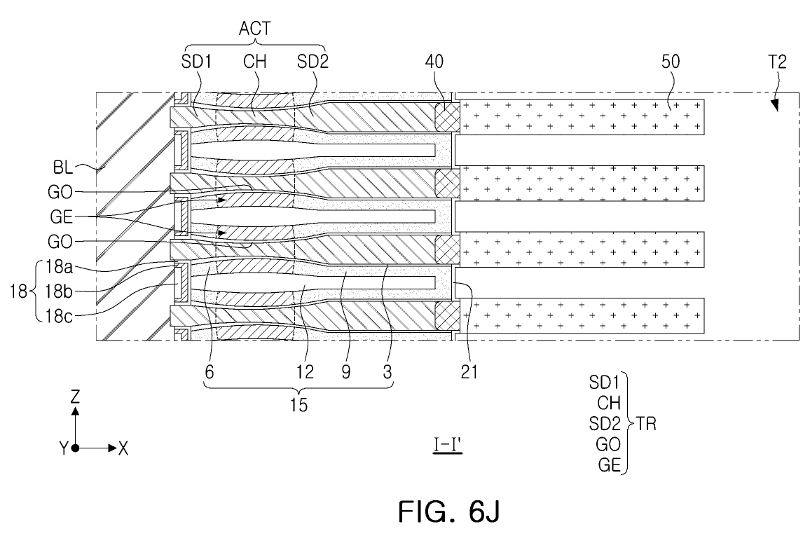

According to the present inventive concept, in order to remove a defect (SM of FIG. 6C) formed between channel material layers (110p of FIG. 6C), an oxidation process may be performed to oxidize the channel material layers 110p. Accordingly, an outer portion of the channel material layer 110p may be oxidized by the oxidation process to form a dielectric layer (IL of FIG. 6D), and the defect (SM of FIG. 6C) may be removed. Accordingly, an insulating material layer (140 of FIGS. 6C and 6D) may be more effectively removed by performing an etching process. In addition, the active pattern ACT may be protected from physical impact, etc. due to the etching process by the dielectric layer IL.

According to the present inventive concept, a semiconductor device including the active pattern ACT having at least one concave portion CP and having different thicknesses in the vertical direction Z along the first horizontal direction X may be provided.

According to the present inventive concept, a semiconductor device including the gate dielectric layer GO having different thicknesses may be provided.

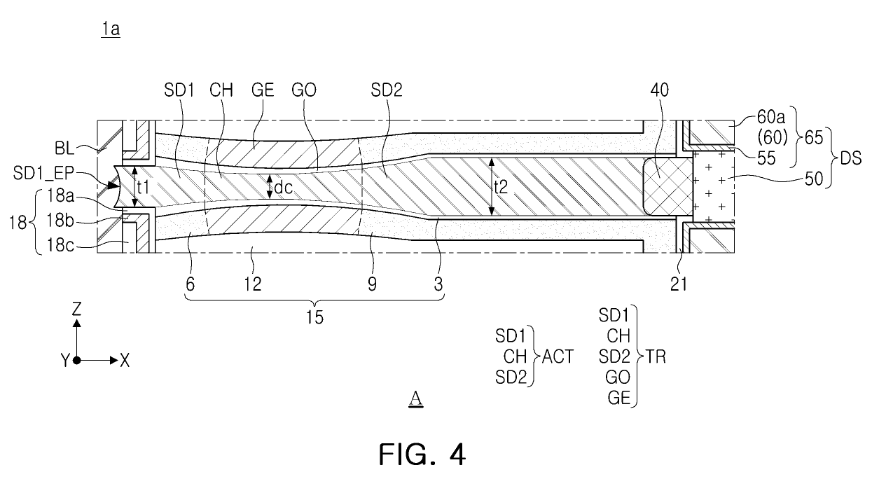

FIG. 4 is a vertical cross-sectional view illustrating an example of a semiconductor device 1a according to an embodiment.

Referring to FIG. 4, except that an end portion SD1_EP of the first source/drain region SD1 has a concave shape in the first horizontal direction X, the semiconductor device 1a may be the same as or similar to the semiconductor device 1 described above with reference to FIGS. 1, 2, 3A, and 3B.

In at least one of the active patterns ACT, the end portion SD1_EP of the first source/drain region SD1 may have a concave shape in the first horizontal direction X. Accordingly, the bit line BL may have a shape convex in the corresponding active pattern ACT in the first horizontal direction X.

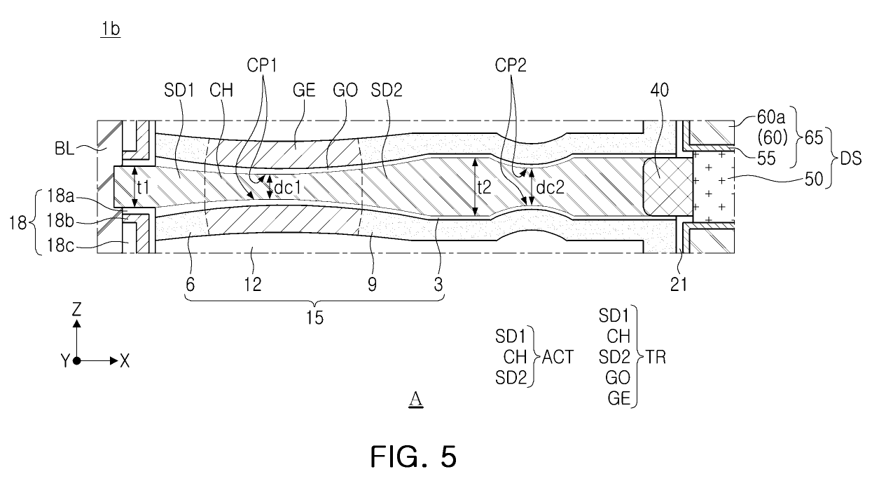

FIG. 5 is a vertical cross-sectional view illustrating an example of a semiconductor device 1b according to an embodiment.

Referring to FIG. 5, except that the active pattern ACT includes a plurality of concave portions, the semiconductor device 1b may be the same as or similar to the semiconductor devices 1 and 1a described above with reference to FIGS. 1, 2, 3A and 3B, and 4.

In the present embodiment, the plurality of concave portions may include a first concave portion CP1 formed across the first source/drain region SD1, the channel region CH, and the second source/drain region SD2 and a second concave portion CP2 formed in the second source/drain region SD2 and closer to the data storage structure DS than the first concave portion CP1. The first concave portion CP1 may be substantially the same as the concave portion CP described above with reference to FIGS. 1, 2, 3A, and 3B, and thus, a detailed description related to the first concave portion CP1 may be omitted.

The second concave portion CP2 may be a portion formed in the second source/drain region SD2. The second concave portion CP2 may be formed closer to the data storage structure DS compared to the first concave portion CP1.

A thickness dc2 of the second source/drain region SD2 in the vertical direction Z may be smaller than the thickness t2 of the second source/drain region SD2 in the vertical direction Z. Here, the thickness dc2 may refer to the minimum thickness of the second source/drain region SD2 defined by the second concave portion CP2. Here, the thickness t2 may refer to the maximum thickness of the second source/drain region SD2.

The thickness dc2 of the second source/drain region SD2 in the vertical direction Z may be greater than the thickness dc1 of the channel region CH in the vertical direction Z. Here, the thickness dc1 may refer to the minimum thickness of the channel region CH defined by the first concave portion CP1.

FIGS. 6A to 6J are vertical cross-sectional views illustrating a method of forming the semiconductor device 1 according to an embodiment of the present inventive concept.

Referring to FIG. 6A, a molded structure MD may be formed on a substrate.

The molded structure MD may include alternately stacked channel material layers 110p and sacrificial layers 112. An upper surface of the substrate may be in contact with one of the sacrificial layers 112. The sacrificial layers 112 may include a material having an etching selectivity with respect to the channel material layers 110p.

In an embodiment, the channel material layers 110p may include silicon, and the sacrificial layers 112 may include silicon-germanium, silicon oxide, silicon nitride, silicon carbide, silicon oxynitride, or combinations thereof. In an embodiment, the channel material layers 110p may include silicon, and the sacrificial layers 112 may include silicon-germanium.

Referring to FIG. 6B, a first trench T1 may be formed.

The first trench T1 may be formed on a first side of the molded structure MD by anisotropically etching the molded structure MD using a predetermined mask layer as an etching mask. The first trench T1 may extend in the second horizontal direction Y.

Thereafter, the sacrificial layers 112 may be partially etched. For example, the sacrificial layers 112 may be partially etched in the first horizontal direction X by supplying an etchant into the first trench T1. Accordingly, the channel material layers 110p may have a protrusion 110p_1 protruding from the side surface of the sacrificial layers 112. The protrusion 110p_1 may be referred to as a preliminary active pattern.

A thickness of the protrusions 110p_1 in the vertical direction Z may vary depending on the first horizontal direction X. For example, a side surface of at least one of the protrusions 110p_1 may be curved. For example, at least one of the protrusions 110p_1 may include at least one concave portion CP. The at least one concave portion CP may be understood as being formed by the etchant in the first trench T1.

Referring to FIG. 6C, the insulating material layer 140 may be formed to fill the first trench (T1 of FIG. 6B).

The insulating material layer 140 may be formed to cover the channel material layers 110p on the side surface of the sacrificial layers 112 by filling the first trench (T1 of FIG. 6B) with an insulating material. A defect SM may be formed in the insulating material layer 140. The defect SM may be understood as being formed due to the concave portion CP formed in the protrusions 110p_1. The defect SM may include a seam or a void. The insulating material layer 140 may include silicon oxide.

Referring to FIG. 6D, an oxidation process may be performed on the protrusions 110p_1 so that the dielectric layer IL may be formed on the protrusions 110p_1.

By performing the oxidation process, the dielectric layer IL may be formed on the upper surface, lower surface, and side surface of each of the protrusions 110p_1. Accordingly, the defect (SM of FIG. 6C) may be removed.

The thickness of a portion of the dielectric layer IL formed on the upper surface and lower surface of the protrusion 110p_1 in the vertical direction Z may decrease in the first horizontal direction X.

Referring to FIG. 6E, the insulating material layer 140 may be removed, and the insulating structure 15 and the gate electrode GE may be formed between the protrusions 110p_1.

The insulating material layer 140 may be removed, and an insulating layer 9 covering the dielectric layer (IL of FIG. 6D) and an insulating layer 12 covering the insulating layer 9 may be formed in sequence. Thereafter, at least a portion of each of the insulating layer 9 and the insulating layer 12 may be removed, and may be filled with a conductive material to form the gate electrode GE. Thereafter, the insulating layer 6 covering the gate electrode GE may be formed. Accordingly, the insulating structure 15 may be formed.

A portion formed on the side surface of the protrusion 110p_1 in the dielectric layers (IL of FIG. 6D) may be removed in the process of forming the insulating structure 15. Accordingly, an end portion of the protrusion 110p_1 may be exposed, and the gate dielectric layer GO and the insulating layer 3 may be defined. The gate dielectric layer GO may be defined as a portion vertically overlapping the gate electrode GE, and the insulating layer 3 may be defined as a portion not vertically overlapping the gate electrode GE. The gate dielectric layer GO and the insulating layer 3 may be a single component, and a boundary between the gate dielectric layer GE and the insulating layer 3 may not be apparent.

The first source/drain regions SD1 may be formed. Forming the first source/drain regions SD1 may include injecting impurities into the end portion of the exposed protrusion 110p_1 by performing a semiconductor process, such as a gas-phase doping (GPD) process.

Referring to FIG. 6F, the insulating structure 18 and the bit line BL may be formed.

The insulating structure 18 may include the insulating layer 18a covering a portion of the first source/drain region SD1 and the insulating structure 15, the insulating layer 18b on the insulating layer 18a, and the insulating layer 18c on the insulating layer 18b.

The bit line BL may be formed to cover the insulating structure 18 and contact an end portion of the first source/drain region SD1.

Referring to FIG. 6G, a second trench T2 may be formed.

The second trench T2 may be formed on a second side of the molded structure MD by anisotropically etching the molded structure MD using a predetermined mask layer as an etching mask. The second trench T2 may extend in the second horizontal direction Y.

Thereafter, the sacrificial layers 112 may be etched. For example, the sacrificial layers 112 may be etched in a direction opposite to the first horizontal direction X by supplying an etchant into the second trench T2. Accordingly, the channel material layers 110p may have the protrusion 110p_2 protruding from the side surface of the sacrificial layers 112.

Referring to FIG. 6H, a first insulating liner 21L and a second insulating liner 22L covering the protrusion 110p_2 may be sequentially formed, and an insulating layer 27 covering the second insulating liner 22L may be formed. Thereafter, at least a portion of the insulating layer 27 may be removed so that a side surface of the protrusion 110p_2 is exposed.

The first insulating liner 21L may be formed of silicon oxide, and the second insulating liner 22L may be formed of silicon nitride. The insulating layer 27 may be formed of oxide. For example, the insulating layer 27 may be formed of silicon oxide.

Referring to FIG. 6I, the protrusion (110p_2 of FIG. 6H) may be etched to form openings OP. The second source/drain regions SD2 may be formed, and the conductive patterns 40 may be formed.

The second source/drain regions SD2 may be formed by performing a semiconductor process, such as a GPD process through the openings OP. Accordingly, the active patterns ACT including the first source/drain region SD1, the channel region CH, and the second source/drain region SD2, each of which is sequentially arranged in the first horizontal direction X, may be defined. Accordingly, the transistor TR may be defined.

The conductive patterns 40 may be formed by reacting a metal element with a semiconductor element of the active patterns ACT exposed by the openings OP. The conductive patterns 40 may form an ohmic contact with the second source/drain regions SD2 of the active patterns ACT exposed by the openings OP. The conductive patterns 40 may be formed of metal silicide.

Referring to FIG. 6J, the conductive pillars 50 may be formed within the openings OP. Thereafter, the first and second insulating liners 21L and 22L and the insulating layer 27 may be removed, and the buffer insulating layer 21 may be defined.

Referring back to FIGS. 2, 3A, and 3B, the dielectric layer 55 and the electrode pattern 60 may be formed. The dielectric layer 55 may conformally cover the exposed surfaces of the conductive pillars 50. The formation of the electrode pattern 60 may include forming a first conductive layer 60a covering the dielectric layer 55 and a second conductive layer 60b on the first conductive layer 60a. The conductive pillars 50, the dielectric layer 55, and the electrode pattern 60 may form the data storage structure DS.

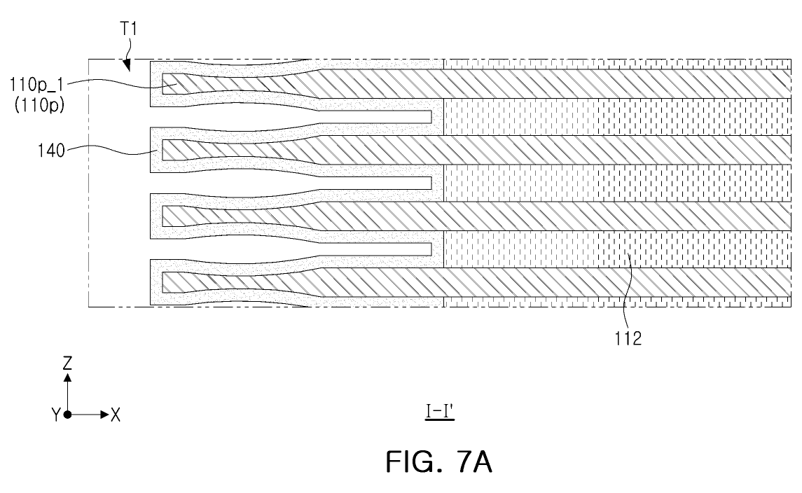

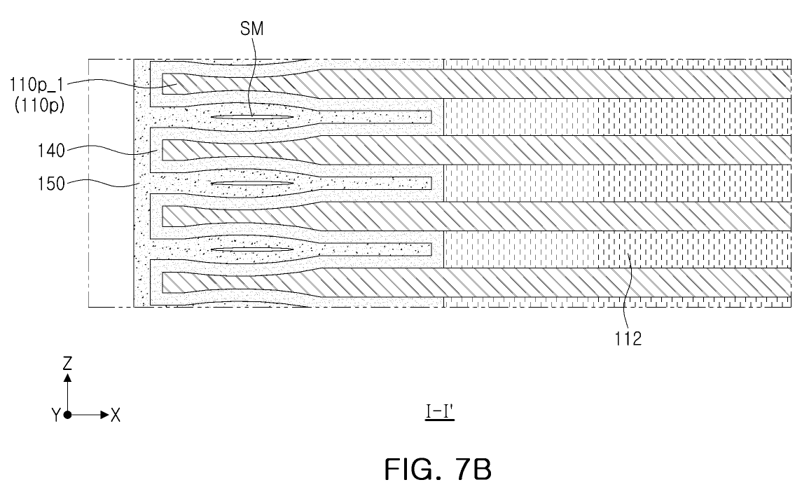

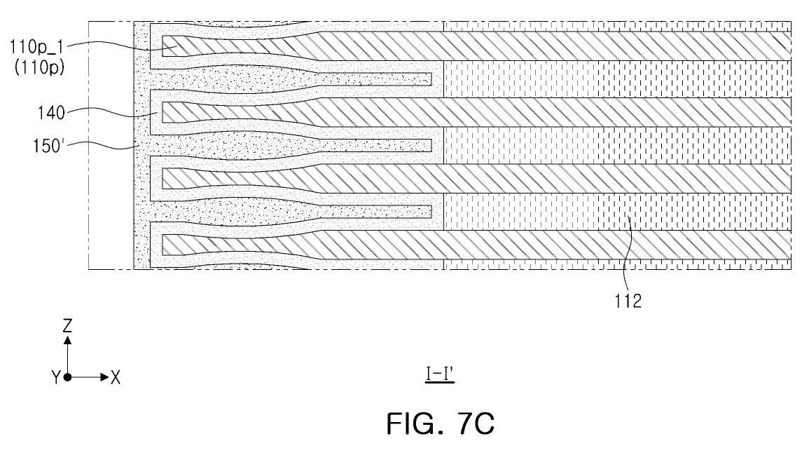

FIGS. 7A to 7C are vertical cross-sectional views illustrating a method of forming a semiconductor device according to an embodiment of the present inventive concept. FIG. 7A may be a vertical cross-sectional view illustrating a forming method that follows FIG. 6B.

Referring to FIG. 7A, the insulating material layer 140 filling the first trench T1 may be formed.

The insulating material layer 140 may be formed to cover an outer surface of the protrusion 110p_1 of the channel material layers 110p and the side surface of the sacrificial layers 112. Compared to that described above with reference to FIG. 6C, the insulating material layer 140 may partially fill the first trench T1. In another perspective, the entire first trench T1 may not be filled with the insulating material layer 140.

Referring to FIG. 7B, the pattern structure 150 covering the insulating material layer 140 may be formed.

The pattern structure 150 may partially fill the first trench T1 and cover the insulating material layer 140. A defect SM may be formed in the pattern structure 150. The defect SM may include a seam or a void.

The pattern structure 150 may include silicon. The pattern structure 150 may be formed by a deposition process, etc. In an embodiment, the pattern structure 150 may include amorphous silicon a-Si. The pattern structure 150 including the amorphous silicon a-Si may be understood for the purpose of oxygen diffusion advantageous during an oxidation process of the pattern structure 150 to be described below with reference to FIG. 7C.

Referring to FIG. 7C, an oxidation process may be performed on the pattern structure 150 to form an insulating pattern structure 150’.

The insulating pattern structure 150’ may be formed by the oxidation process, and thus the defect (SM of FIG. 7B) may be removed.

Subsequently, the insulating material layer 140 and the insulating pattern structure 150’ may be removed, and a dielectric layer may be formed on the protrusion 110p_1. Thereafter, a semiconductor device may be provided through the forming methods described above with reference to FIGS. 6E to 6J.

According to an aspect of the present inventive concept, a method of manufacturing a semiconductor device includes: forming a molded structure including alternately stacked channel material layers and sacrificial layers; etching a first side of the molded structure to form a first trench, in which at least a portion of each of the sacrificial layers is etched in a first horizontal direction by the first trench and each of the channel material layers has a preliminary active pattern protruding from a side surface of the sacrificial layers; forming an insulating material layer covering the preliminary active pattern of the channel material layers on the side surface of the sacrificial layers; forming a dielectric layer on the preliminary active pattern of the channel material layers; removing the insulating material layer and forming a gate electrode between the preliminary active patterns; and forming an active pattern from the preliminary active pattern. The active pattern includes a first source/drain region, a channel region, and a second source/drain region sequentially arranged in the first horizontal direction, at least a portion of a side surface of each of the first source/drain region, the channel region, and the second source/drain region is curved, a thickness of the channel region in a vertical direction is smaller than a thickness of the first source/drain region in the vertical direction, and a thickness of the first source/drain region in the vertical direction is smaller than a thickness of the second source/drain in the vertical direction.

The method may further include forming a bit line on the first side of the molded structure, in which the bit line may be electrically connected to the first source/drain region.

The forming of the dielectric layer may include oxidizing the preliminary active pattern through an oxidation process.

The active pattern may have a shape concave toward the center of the active pattern.

The gate electrode may vertically overlap the channel region, and the gate electrode may have a shape convex in a direction toward the channel region.

A thickness of the dielectric layer in a vertical direction may decrease along the first horizontal direction.

The first source/drain region may include a first portion adjacent to the channel region; and a second portion connected to the first portion and contacting the bit line, and a thickness of the first portion in the vertical direction may decrease along the first horizontal direction.

An end portion of the second portion of the first source/drain region may have a side surface having a concave shape in the first horizontal direction.

The method may further include etching the second side of the molded structure to form a second trench; and forming a data storage structure electrically connected to the second source/drain region within the second trench.

The second source/drain region may include a first portion adjacent to the channel region; and a second portion connected to the first portion and adjacent to the data storage structure, in which a thickness of the first portion in the vertical direction may increase in the first horizontal direction.

According to the embodiments of the present inventive concept, the semiconductor device with improved reliability and improved performance and the method of manufacturing the same may be provided.

Specifically, according to the embodiments of the present inventive concept, the semiconductor device including the active pattern having at least one concave portion and having different thicknesses in the vertical direction along the first horizontal direction may be provided.

The various advantageous advantages and effects of the present inventive concept are not limited to the above-described contents and will be more easily understood in the course of describing specific embodiments of the present inventive concept.

While embodiments have been shown and described above, it will be apparent to those skilled in the art that modifications and variations could be made without departing from the scope of the present inventive concept as defined by the appended claims.

What is claimed is:

1. A semiconductor device comprising:
transistors stacked in a vertical direction;
a bit line electrically connected to a first side of each of the transistors; and
a data storage structure electrically connected to a second side of each of the transistors,
wherein the each of the transistors includes:
an active pattern including a first source/drain region, a channel region, and a second source/drain region arranged sequentially in a first horizontal direction, the first horizontal direction being perpendicular to the vertical direction and a direction from the bit line toward the data storage structure;
a gate electrode vertically overlapping the channel region; and
a gate dielectric layer disposed between the gate electrode and the channel region,
wherein at least a portion of a side surface of each of the first source/drain region, the channel region, and the second source/drain region is curved,
a thickness of the channel region in the vertical direction is smaller than a thickness of the first source/drain region in the vertical direction, and
a thickness of the first source/drain region in the vertical direction is smaller than a thickness of the second source/drain in the vertical direction.

2. The semiconductor device of claim 1, wherein the active pattern has a shape concave toward a center of the active pattern, the center being defined in a direction parallel to the first horizontal direction.

3. The semiconductor device of claim 1, wherein the gate electrode has a shape convex in a direction toward the channel region.

4. The semiconductor device of claim 1, wherein a thickness of the gate dielectric layer in the vertical direction decreases along the first horizontal direction.

5. The semiconductor device of claim 1, further comprising:
insulating structures disposed between the transistors and the bit line,
wherein the first source/drain region includes:
a first portion adjacent to the channel region; and
a second portion connected to the first portion and contacting the bit line between the insulating structures, and
a thickness of the first portion in the vertical direction decreases along the first horizontal direction.

6. The semiconductor device of claim 5, wherein an end portion of the second portion of the first source/drain region has a side surface having a concave shape in the first horizontal direction.

7. The semiconductor device of claim 1, wherein
the second source/drain region includes:
a first portion adjacent to the channel region; and
a second portion connected to the first portion and adjacent to the data storage structure, and
a thickness of the first portion in the vertical direction increases in the first horizontal direction.

8. The semiconductor device of claim 1, wherein a length of the second source/drain region in the first horizontal direction is greater than a length of the first source/drain region in the first horizontal direction.

9. The semiconductor device of claim 1, wherein
the data storage structure includes:
conductive pillars each extending in the first horizontal direction and electrically connected to the second source/drain region;
an electrode pattern covering the conductive pillars; and
a dielectric layer disposed between the conductive pillars and the electrode pattern.

10. The semiconductor device of claim 9, further comprising
conductive patterns disposed between the transistors and the conductive pillars,
wherein a first conductive pattern among the conductive patterns includes a metal-semiconductor compound region in contact with the second source/drain region of a corresponding first transistor among the transistors.

11. A semiconductor device comprising:
a memory structure; and
a peripheral structure overlapping the memory structure in a vertical direction and including a peripheral circuit,
wherein the memory structure includes:
transistors stacked in the vertical direction,
each of the transistors including
an active pattern including a first source/drain region, a channel region, and a second source/drain region sequentially arranged in a first horizontal direction, perpendicular to the vertical direction, the active pattern having at least one concave portion,
a gate electrode vertically overlapping the channel region and having at least one convex portion corresponding to the at least one concave portion and being convex toward the active pattern, and
a gate dielectric layer disposed between the gate electrode and the channel region;
a bit line electrically connected to the first source/drain region of the transistors; and
a data storage structure electrically connected to the second source/drain region of the transistors.

12. The semiconductor device of claim 11, wherein a thickness of the gate dielectric layer in the vertical direction decreases along the first horizontal direction.

13. The semiconductor device of claim 11, wherein
the first source/drain region includes:
a 1-1 portion adjacent to the channel region; and
a 1-2 portion connected to the 1-1 portion and adjacent to the bit line, and
the second source/drain region includes:
a 2-1 portion adjacent to the channel region; and
a 2-2 portion connected to the 2-1 portion and adjacent to the data storage structure, and
the at least one concave portion includes a first concave portion on the 1-1 portion of the first source/drain region, the channel region, and the 2-1 portion of the second source/drain region.

14. The semiconductor device of claim 13, wherein
a thickness of the 1-2 portion of the first source/drain region in the vertical direction is greater than a thickness of the channel region in the vertical direction, and
a thickness of the 2-2 portion of the second source/drain region in the vertical direction is greater than the thickness of the 1-2 portion of the first source/drain region in the vertical direction.

15. The semiconductor device of claim 13, wherein the at least one concave portion further includes a second concave portion on the 2-2 portion of the second source/drain region.

16. The semiconductor device of claim 15, wherein a thickness of the first concave portion in the vertical direction is smaller than a thickness of the second concave portion in the vertical direction.

17. A semiconductor device comprising:
an active pattern extending in a first horizontal direction and having at least one concave portion,
the active pattern including
a first source/drain region;
a second source/drain region; and
a channel region disposed between the first source/drain region and the second source/drain region,
wherein the at least one concave portion is defined along a side surface of the channel region and the first and second source/drain regions, which are centered on the channel region;
a bit line extending in a vertical direction and contacting the first source/drain region of the active pattern; and
a gate electrode overlapping at least a portion of the channel region of the active pattern in the vertical direction and extending in a second horizontal direction, intersecting the first horizontal direction.

18. The semiconductor device of claim 17, further comprising a gate dielectric layer disposed between the gate electrode and the channel region, the gate dielectric layer having a thickness in the vertical direction, the thickness decreasing along the first horizontal direction.

19. The semiconductor device of claim 17, wherein a thickness of the channel region in the vertical direction is smaller than a thickness of each of the first source/drain region and the second source/drain region in the vertical direction.

20. The semiconductor device of claim 17, further comprising:
a metal-semiconductor compound layer in contact with the second source/drain region; and
a data storage structure in contact with at least a portion of the metal-semiconductor compound layer.
